(19) United States
(12) Patent Application Publication
(10) Pub. No.: US 2012/0180852 A1
(43) Pub. Date: Jul. 19, 2012

(54) ETCHING COMPOSITION

(75) Inventors: LAP-TAK ANDREW CHENG, NEWARK, DE (US); ZHE CHENG, WILMINGTON, DE (US); CHENG-YU LAI, WEST GROVE, PA (US); MEIJUN LU, HOCKESSIN, DE (US)

(73) Assignee: E.I. DU PONT DE NEMOURS AND COMPANY, Wilmington, DE (US)

(21) Appl. No.: 13/005,793

(22) Filed: Jan. 13, 2011

(51) Int. Cl. H01L 31/02; C09K 13/00; C09K 13/04; H01L 31/18

(52) U.S. Cl. 136/252; 438/57; 252/79.1; 252/79.2; 257/E31.001

(57) ABSTRACT

The invention relates to a chemical etching composition and to methods to produce a photovoltaic cell with transparent regions. The methods comprise a step to locally dispense an etching composition on the photovoltaic cell in a pattern, or adjacent to the edge thereof; an optional step to apply heat to the cell; and a step to remove the etching composition. The methods are further characterized by the chemical removal of one or more chemically distinctive layers of the photovoltaic cell where the etching composition is applied. The methods may be used to produce a thin film photovoltaic panel.

### FIELD OF THE INVENTION

This invention relates to a chemical etching method for use in thin-film photovoltaics.

### BACKGROUND

A photovoltaic (“PV”) cell converts radiation energy into electrical energy. The energy conversion occurs as the result of the PV effect. Of particular recent interest is the large scale and cost effective conversion of solar radiation (sunlight) into electricity using arrays of PV cells assembled into solar panels. Thin film PV cells are typically manufactured via a multi-step process, one stage of which is the assembly of a PV laminate on a substrate. Physical vapor and chemical vapor deposition steps for manufacturing of the PV laminates are used to deposit transparent conductive oxide (TCO), absorbers such as amorphous silicon, and metallic layers on a substrate. These layers are usually opaque.

WO 2001/006555 describes etching a PV device with a solution comprising nitric acid, phosphoric acid and polyvinyl alcohol. U.S. Pat. No. 7,196,018 describes etching a PV device with a caustic solution. U.S. Pat. No. 4,872,925 describes etching a PV device with a paste comprising nitric acid and hydrofluoric acid.

JP 2003/002,685 discloses a composition for etching sandblasted glass that contains NaOH, Na₂CO₃, CaCl₂ or Ca(OH)₂.

A need nevertheless remains for an improved etching material, and for improved methods of etching, to produce PV cells.

### SUMMARY

In one embodiment, the inventions hereof provide a method of etching comprising the steps of:

(a) providing a photovoltaic cell that comprises (i) a substrate; (ii) a photovoltaic laminate that comprises a front electrode layer, a back electrode layer, and one or more photovoltaic junction layers disposed between the front electrode layer and the back electrode layer; wherein the front electrode layer is disposed on the substrate; and (b) depositing an etching composition on the back electrode layer of the photovoltaic laminate, wherein the etching composition comprises (i) an oxidizing acid, (ii) an oxide remover, (iii) a solvent, (iv) a dispersing additive, (v) a binder, and (vi) optionally, a filler.

In another embodiment, the etching composition mentioned above can contain, by total weight of the whole composition, (i) about 10 to about 65% by weight of an oxidizing acid, (ii) about 1 to about 25% by weight of an oxide remover, (iii) about 5 to about 60% by weight of a solvent, (iv) about 0.1 to about 30% by weight of a dispersing additive, (v) about 0.5 to about 30% by weight of a binder, and (vi) optionally, 0 to about 10% by weight of a filler.

In a further embodiment, the inventions hereof provide a method as described above wherein a photovoltaic cell that has been etched by such method is incorporated into an electrical generating device.

In yet another embodiment, the inventions hereof provide a composition consisting essentially of (a) 10 to 65% by weight of an oxidizing acid; (b) about 1 to about 25% by weight of an oxide remover; (c) about 5 to about 60% by weight of a solvent; (d) about 0.1 to about 30% by weight of an dispersing additive; (e) about 0.5 to about 30% by weight of a binder; and (f) 0 to about 10% by weight of an optional filler; where percent by weight is of the total weight of all components of the composition together.

In yet another embodiment, the inventions hereof provide an apparatus comprising a transparent substrate and a photovoltaic laminate disposed on the substrate, wherein about 40% to about 95% of the surface area of the substrate is occupied by the photovoltaic laminate, and 5% to about 60% of the surface area of the substrate transmits visible light.

In yet another embodiment, the inventions hereof provide an apparatus that receives incident light and comprises a first component to generate electricity from the portion of the incident light striking the first component, and a second component that is attached to the first component and transmits any visible wavelengths of the portion of the incident light striking the second component.

The inventions hereof provide an improved etching material, and improved methods of etching, to produce partially transparent PV cells and PV cells with electrically isolated edges. In various embodiments, the inventions hereof enable the production of PV cells by a single application of an etching composition.

### BRIEF DESCRIPTION OF THE DRAWINGS

FIG. 1 is a side elevation view of a thin-film PV cell having a substrate, and a PV laminate disposed thereon.

FIGS. 2 and 4 show, in a side elevation, locations on a PV laminate in which etching composition has been deposited in a pattern.

FIGS. 3 and 5 show locations where the layers of a PV laminate have been removed.

FIG. 6 shows peripheral and interior regions of a PV laminate.

FIGS. 7˜9 show, in a plan view, locations on a PV laminate in which etching composition has been deposited in a pattern.

### DETAILED DESCRIPTION

In order to produce a partially transparent PV cell, it is useful to remove portions of the PV laminate to leave exposed portions of the substrate on which the laminate is disposed, whereupon those portions of the substrate from which the PV laminate has been removed can transmit visible light when the substrate is transparent.

According to this invention, a thin-film silicon PV cell contains, in addition to other components, a substrate and a PV laminate. The PV laminate has a front electrode layer, a PV junction layer, and a back electrode layer. The PV laminate is a component of the PV cell, along with the laminate, and the PV laminate is disposed on the substrate. The front electrode layer of the laminate is disposed on the substrate, one or more the PV junction layers is disposed between the front and back electrode layers.

In one embodiment, this invention provides a method for the etching of a PV cell. The first step in the method is providing a PV cell that contains a PV laminate and a substrate (in the description and claims of this specification, the term “substrate” will be understood to also include a superstrate). The PV laminate is composed of a front electrode layer, a back electrode layer, and one or more PV junction layers disposed between the front electrode and the back electrode layers. The PV laminate is disposed on a surface of the substrate.

The substrate can be prepared from a material having good structural integrity such as glass, metal or a polymer. In a preferred embodiment, the substrate is prepared from a transparent material such as glass or a transparent polymer. Transparent polymers suitable for use as a substrate include polycarbonate, polymethylmethacrylate, polyethyleneterephthalate and polysulfone.

The front electrode layer is composed of one or more layers of metals, such as silver, and/or metal oxides, such as impurity-doped tin oxide, zinc oxide or indium oxide. The back electrode is composed of one or more layers of metals, such as silver, and/or metal oxides such as ZnO. The PV junction layer(s) is composed of doped and intrinsic (undoped) layers of semiconductors such as silicon and silicon alloys, and is disposed between the front and back electrode layers. In a preferred embodiment, one or both of the front electrode layer and the back electrode layer is transparent.

As the front electrode layer is attached to the substrate, access to the PV laminate may be obtained from the back electrode layer, and the next step thus involves depositing an etching composition on the back electrode layer of the laminate. The etching composition may be applied as a paste to the surface of the back electrode layer by a technique such as screen printing, and may, if desired, be applied in a regularly, repeating pattern.

An etching composition as used herein contains (i) an oxidizing acid, (ii) an oxide remover, (iii) a solvent, (iv) a dispersing additive, (v) a binder, and (vi) optionally, a filler. In a preferred embodiment, the etching composition can contain, by total weight of the whole composition,
about 10 to about 65% by weight of an oxidizing acid,
about 1 to about 25% by weight of an oxide remover;
about 5 to about 60% by weight of a solvent;
about 0.1 to about 30% by weight of a dispersing additive;
about 0.5 to about 30% by weight of a binder; and, optionally, 0 to about 10% by weight of a filler

While the etching composition is deposited on the back electrode layer, the PV cell may be heated to a temperature in the range of about 20° C. to about 40° C. for a period of about 1 to about 5 minutes. The etching composition may be removed from contact with the PV cell by a process such as washing with a solvent such as water.

In the composition formed by the components of the etching composition, an oxidizing acid is used to oxidize reduced species in the materials from which the PV laminate is made, and aid in their dissolution. Materials suitable for use in the etching composition as an oxidizing acid include those selected from the group consisting of nitric acid and HClO₄.

An oxide remover is used in the etching composition hereof to attack the adhesion of oxides such as silicon oxide, to assist in the removal of the adhered oxides, and allow the penetration of other etching composition constituents to the PV laminate. Materials suitable for use in the etching composition as an oxide remover include those selected from the group consisting of NH₄F, NH₄HF₂, HF, KF and KHF₂.

A solvent is used in the etching composition hereof to carry the other constituents of the etching composition, and to dissociate the oxidizing acid. Materials suitable for use in the etching composition as a solvent include those selected from the group consisting of water, ethylene glycol and monobutyl ether.

A dispersing additive is used in the etching composition hereof to aid in dispersion of particles formed by the attack of the etching composition on the PV laminate, and to aid in allowing further dissolution by the etching composition. Materials suitable for use in the etching composition as a dispersing solvent include those selected from the group consisting of glycolic acid, acetic acid and formic acid.

A binder is used in the etching composition hereof to give the etching composition elevated viscosity to enable the printing of the etching composition in a pattern, and/or to prevent the etching composition from spreading to portions of over the surface of the PV laminate where it is not desired. Materials suitable for use in the etching composition as a binder include those selected from the group consisting of poly(vinyl alcohol), poly(ethylene oxide), poly(vinyl pyrrolidone) and poloxamers.

In yet another embodiment, this invention provides an etching composition that consists essentially of about 10 to about 65% by weight of an oxidizing acid; about 1 to about 25% by weight of an oxide remover; about 5 to about 60% by weight of a solvent; about 0.1 to about 30% by weight of a dispersing additive; about 0.5 to about 30% by weight of a binder; and, optionally, 0 to about 10% by weight of a filler. The composition described above omits therefrom any Group I (e.g. Li, Na, K or Rb) or Group II (e.g. Be, Mg, Ca, Sr or Ba) species since their presence in the composition would cause the composition to attack glass, which is the frequent choice of material from which to make a transparent substrate in a PV cell.

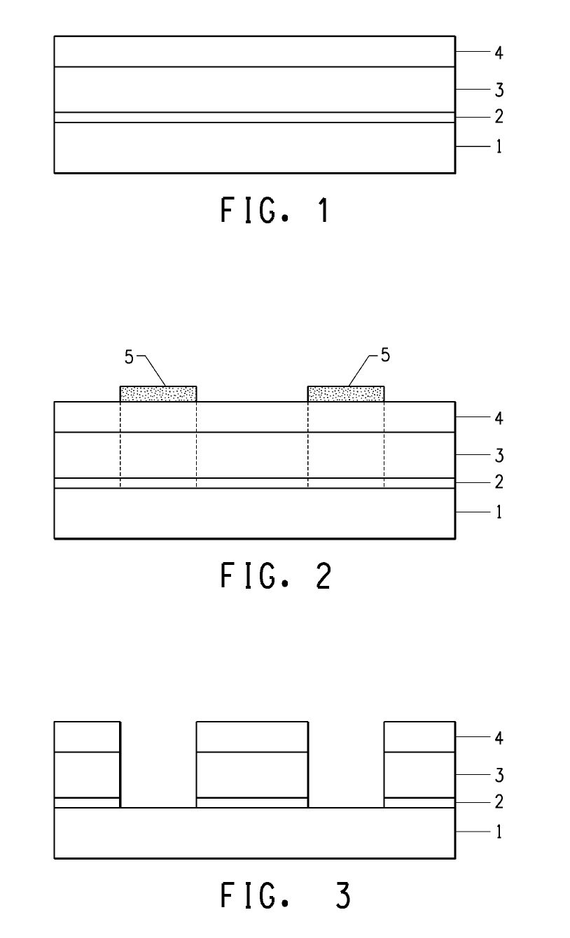

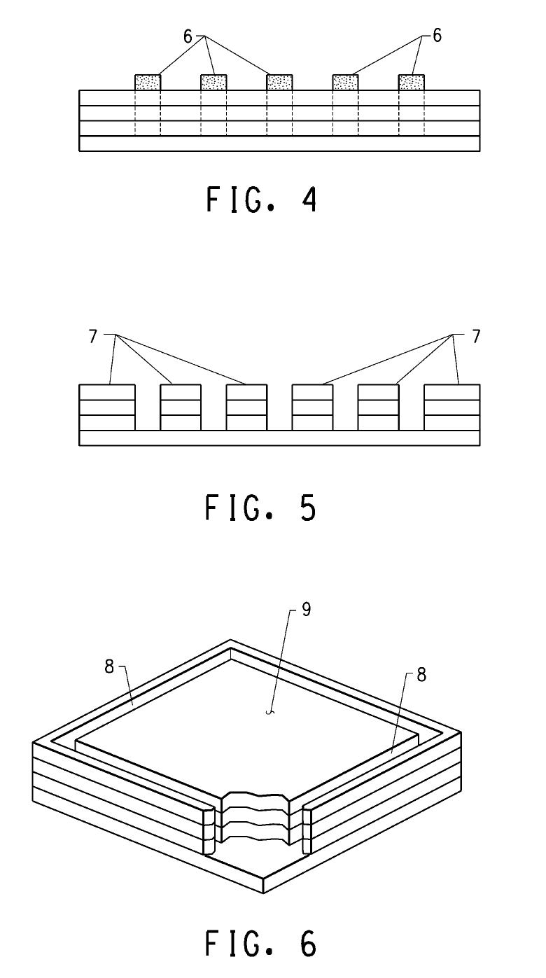

In yet another embodiment hereof, the etching composition can be used to etch away or remove various portions of the PV laminate that lie in the interior region thereof, i.e. not adjacent to the edge of the laminate. As shown, for example, in FIG. 1, a PV cell comprises a substrate 1, a front electrode layer 2, a PV junction (semiconductor) layer 3, and a back electrode layer 4. Etching composition may be applied in the interior region of the PV cell to etch away and remove the layers of the PV laminate down to the substrate. As shown in FIG. 2, etching composition is thus applied to regions 5 of the back electrode layer (or is applied to regions 6 thereof as shown in FIG. 4); and as shown in FIG. 3, after the etching composition has been washed away from the PV cell, the regions of the laminate to which the etchant was applied are also removed, and the substrate is exposed at those locations.

The region (or, in the aggregate, the regions) of the back electrode layer to which etching composition is applied can occupy at least about 10%, or at least about 20%, or at least about 30%, or at least about 40%, or at least about 50%, or at least about 60%, of the area of the surface of the back electrode layer. Correspondingly, then, as shown in FIG. 5, the regions 7 of the PV laminate remaining after the etching composition, and etched portions of laminate, have been removed can occupy at least about 40%, or at least about 50%, or at least about 60%, or at least about 70%, or at least about 80%, or at least about 90%, of the area of the surface of the back electrode layer.

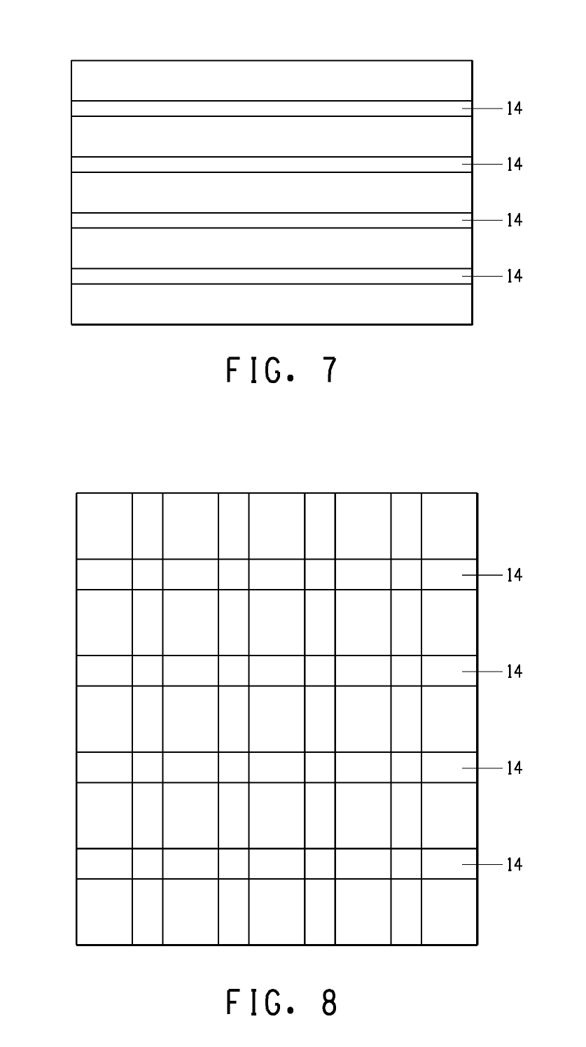

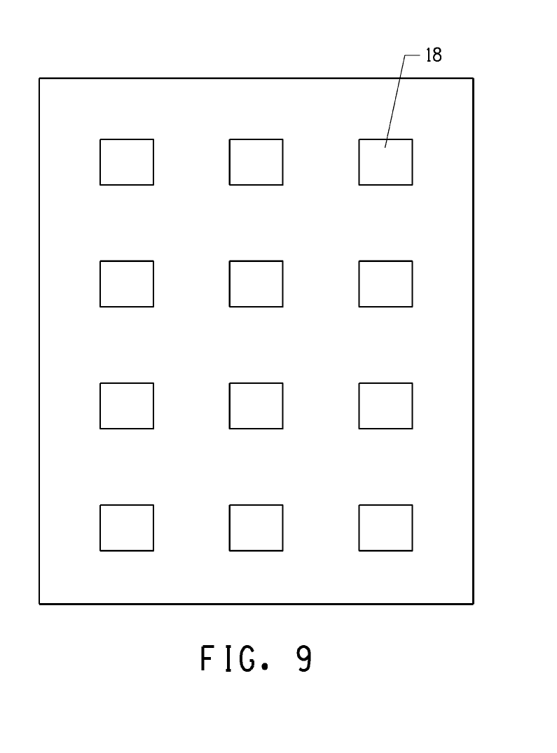

When the PV cell has been provided with a transparent substrate, the transparent substrate will be able to transmit visible light in any region where the PV laminate has been removed down to the surface of the substrate. For this purpose, the etching composition can be deposited on the back electrode layer, which forms the exposed surface of the laminate, in a regularly repeating pattern. The pattern may conveniently be a first series of parallel strips 14 as shown in FIG. 7. The pattern may also, however, include a second series of parallel strips 16, where the first series of parallel strips is orthogonal to the second series of parallel strips, as shown in FIG. 8. In yet another embodiment, the pattern in which the etchant is deposited may be a plurality of shapes, wherein each shape is equidistantly spaced from each other shape. Such shapes may be selected, for example, from the group consisting of circles, ovals, squares, rectangles, triangles and polygons, as indicated by the example of the squares 18 shown in FIG. 9. In yet other embodiments, however, when the etching composition is not applied to the entire surface of the back electrode layer, it is not required that the etchant be deposited in any kind of pattern, that any shapes thereby formed be symmetric, or that any shapes thereby formed be equidistant from each other. The etchant could be applied in any manner that produces custom designed, non-regular shapes with non-regular spacing, or in theory could be applied in any random manner. It is believed, however, that the embodiments in which the etchant is applied in a pattern and/or with regular spacing will have greater commercial value.

Wherever the etching composition is applied, the PV laminate in that region will be removed, and the laminate in the remaining region will be left intact. When the substrate is transparent, the PV cell is then able to transmit visible light in the region(s) where the laminate has been removed, and is able to generate electricity from the region(s) where the laminate still resides. In various embodiments, for example, after the etchant and etched regions of the PV laminate have been removed, about 40% to about 95%, or about 60% to about 80%, of the surface area of the substrate is occupied by the PV laminate. Correspondingly, about 5% to about 60%, or about 20% to about 40%, of the surface area of the substrate is then able to transmit visible light. When the etchant is deposited in only certain selected regions of the surface of the back electrode layer, the PV laminate will be removed in only those regions, and the PV cell thereupon becomes an apparatus in which, when it receives incident light, a first component (the regions in which the laminate remains) generates electricity from the portion of the incident light that strikes the remaining PV laminate, and a second component (the regions where the laminate has been removed) that is attached to the first component and transmits any visible wavelengths of the portion of the incident light that strikes the exposed substrate in the PV cell of the apparatus.

Whether or not the substrate of a PV cell is transparent, the PV laminate on the substrate contains edges and a peripheral region adjacent to the edges. The peripheral region of a laminate can be the region that is occupied by an edge-adjacent strip, where there is an edge-adjacent strip adjacent to each of the edges of the laminate. Each edge-adjacent strip of the peripheral region can be up to about 0.5 cm wide, or up to about 1.0 cm wide, or up to about 1.5 cm wide, or up to about 2.0 cm wide, or up to about 2.5 cm wide, or up to about 3.0 cm wide, and thus extend a distance of that same amount away from the edge of the laminate into the interior of the laminate. When material is deposited to form the electrode layers of the laminate on the substrate, the electrode layer material can be deposited up to, and (unintentionally) in some instances over, the edge of the substrate or the previously formed electrode layers. This imprecise deposition of electrode layer material can lead to electrical shorts within the PV cell that destroy its electrical generating function. The edge region is also vulnerable to environmental corrosion even after the PV laminate has been encapsualted. Therefore it is necessary to electrically isolate the interior of the PV laminate from the edge regions thereof, and for such purpose a strip of the laminate can be removed from the surface of the substrate in a selected width within the peripheral region.

For such purpose, the methods of this invention thus further provide a method of etching involving depositing an etching composition on the back electrode layer of a PV laminate (as described above) wherein the etching composition is applied, on the surface of the back electrode layer, to a strip adjacent to one or more edges of the back electrode layer. The etching composition is thus applied to the laminate for the purpose of removing one or more layers of the laminate within the peripheral region. As shown in FIG. 6, for example, one or more layers of the laminate can be removed from the edge laminate 8 back to the location where the interior 9 of the laminate is intended to remain. The etching composition can be applied to a strip adjacent to one of the edges of the back electrode layer, one or more of the edges of the back electrode layer, or to each of the edges of the back electrode layer. The area occupied together by all edge-adjacent strips on which etching composition is deposited can be at least about 1% of the area of the surface of the back electrode layer, or at least about 2% of the area of the surface of the back electrode layer, or at least about 4% of the area of the surface of the back electrode layer, or at least about 6% of the area of the surface of the back electrode layer, or at least about 8% of the area of the surface of the back electrode layer, and yet no more than about 20% of the area of the surface of the back electrode layer, or no more than about 18% of the area of the surface of the back electrode layer, or no more than about 16% of the area of the surface of the back electrode layer, or no more than about 12% of the area of the surface of the back electrode layer, or no more than about 10% of the area of the surface of the back electrode layer.

In depositing etching composition on edge-adjacent strips within the peripheral region of the PV laminate, the etching composition can be applied by dispensers selected from the group consisting of nozzles, screens, rollers, brushes, and slot dies. The methods further involve optionally heating the etching composition, removing the etching composition after a pre-determined time, and/or rinsing the peripheral region to remove etching composition and etched electrode layer material. For example, in one embodiment, a hot plate can be used to raise the temperature of the etchant through the substrate to a temperature up to about 150° C. in order to reduce the required etching time. In a further embodiment, the etching composition is allowed to chemically etch the PV laminate for a period, for example, of about 1 to about 2 minutes depending on the concentration of the etchant and the thickness of the electrode layers in the laminate. In yet another embodiment, the substrate can be sprayed with high pressure water or aqueous alkaline in order to remove the etching composition.

In a further embodiment, this invention provides a method wherein a PV cell that has been etched according to a method as described herein, is then incorporated into an electrical generating device by attachment to the additional components utilized for the purpose of actually collecting a current flow.

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

In this specification, unless explicitly stated otherwise or indicated to the contrary by the context of usage, where an embodiment of the subject matter hereof is stated or described as comprising, including, containing, having, being composed of or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present.

In this specification, unless explicitly stated otherwise or indicated to the contrary by the context of usage, amounts, sizes, ranges, formulations, parameters, and other quantities and characteristics recited herein, particularly when modified by the term “about”, may but need not be exact, and may also be approximate and/or larger or smaller (as desired) than stated, reflecting tolerances, conversion factors, rounding off, measurement error and the like, as well as the inclusion within a stated value of those values outside it that have, within the context of this invention, functional and/or operable equivalence to the stated value.

What is claimed is:

1. A method of etching comprising the steps of:
(a) providing a photovoltaic cell that comprises (i) a substrate; (ii) a photovoltaic laminate that comprises a front electrode layer, a back electrode layer, and one or more photovoltaic junction layers disposed between the front electrode layer and the back electrode layer; wherein the front electrode layer is disposed on the substrate; and
(b) depositing an etching composition on the back electrode layer of the photovoltaic laminate, wherein the etching composition comprises (i) an oxidizing acid, (ii) an oxide remover, (iii) a solvent, (iv) a dispersing additive, (v) a binder, and (vi) optionally, a filler.

2. A method according to claim 1 wherein the etching composition is screen printed on the back electrode layer of the photovoltaic laminate.

3. A method according to claim 1 further comprising a step (c) of heating the photovoltaic laminate while the etching composition is deposited thereon; and/or a step (d) of removing the etching composition from contact with the photovoltaic laminate.

4. A method according to claim 3 wherein the photovoltaic laminate is washed to remove the etching composition.

5. A method according to claim 1 wherein the content of the etching composition comprises, by total weight of the whole composition, (i) about 10 to about 65% by weight of an oxidizing acid, (ii) about 1 to about 25% by weight of an oxide remover, (iii) about 5 to about 60% by weight of a solvent, (iv) about 0.1 to about 30% by weight of a dispersing additive, (v) about 0.5 to about 30% by weight of a binder, and (vi) optionally, 0 to about 10% by weight of a filler.

6. A method according to claim 1 wherein
(a) the oxidizing acid is selected from the group consisting of nitric acid and HClO₄; or
(b) wherein the oxide remover is selected from the group consisting of NH₄F, NH₄HF₂, HF, KF and KHF₂; or
(c) wherein the solvent is selected from the group consisting of water, ethylene glycol and monobutyl ether; or
(d) wherein the dispersing additive is selected from the group consisting of glycolic acid, acetic acid and formic acid; or
(e) wherein the binder is selected from the group consisting of poly(vinyl alcohol), poly(ethylene oxide), poly(vinyl pyrrolidone) and poloxamers.

7. A method according to claim 1 wherein the etching composition is applied in a pattern on the surface of the back electrode layer.

8. A method according to claim 7 wherein the pattern occupies at least about 10% of the area of the surface of the back electrode layer.

9. A method according to claim 7 wherein the pattern comprises a first series of parallel strips.

10. A method according to claim 9 wherein the pattern further comprises a second series of parallel strips, wherein the first series of parallel strips is orthogonal to the second series of parallel strips.

11. A method according to claim 7 wherein the pattern comprises a plurality of shapes, wherein each shape is equidistantly spaced from each other shape.

12. A method according to claim 1 wherein the etching composition is applied, on the surface of the back electrode layer, to a strip adjacent to one or more edges of the back electrode layer.

13. A method according to claim 12 wherein the etching composition is applied to a strip adjacent to each edge of the back electrode layer.

14. A method according to claim 12 wherein the area occupied together by all edge-adjacent strips is at least 1% of the area of the surface of the back electrode layer.

15. A method according to claim 1 wherein at least one of the substrate, the front electrode layer and the back electrode layer is transparent.

16. A method according to claim 1 further comprising incorporating the photovoltaic cell into an electrical generating device.

17. A composition consisting essentially of (a) 10 to 65% by weight of an oxidizing acid; (b) about 1 to about 25% by weight of an oxide remover; (c) about 5 to about 60% by weight of a solvent; (d) about 0.1 to about 30% by weight of an dispersing additive; (e) about 0.5 to about 30% by weight of a binder; and (f) 0 to about 10% by weight of an optional filler; where percent by weight is of the total weight of all components of the composition together.

18. A composition according to claim 17 wherein
(a) the oxidizing acid is selected from the group consisting of nitric acid and HClO₄; or
(b) wherein the oxide remover is selected from the group consisting of NH₄F, NH₄HF₂, HF, KF and KHF₂; or
(c) wherein the solvent is selected from the group consisting of water, ethylene glycol and monobutyl ether; or
(d) wherein the dispersing additive is selected from the group consisting of glycolic acid, acetic acid and formic acid; or
(e) wherein the binder is selected from the group consisting of poly vinyl alcohol, poly ethylene oxide, poly vinyl pyrrolidone and poloxamers.

19. An apparatus comprising a transparent substrate and a photovoltaic laminate disposed on the substrate, wherein about 40% to about 95% of the surface area of the substrate is occupied by the photovoltaic laminate, and 5% to about 60% of the surface area of the substrate transmits visible light.

20. An apparatus that receives incident light and comprises a first component to generate electricity from the portion of the incident light striking the first component, and a second component that is attached to the first component and transmits any visible wavelengths of the portion of the incident light striking the second component.
